(19) United States
(12) Patent Application Publication
(10) Pub. No.: US 2026/0293706 A1
(43) Pub. Date: Sep. 24, 2026

(54) SEMICONDUCTOR DEVICE

(71) Applicants: KABUSHIKI KAISHA TOSHIBA, Kawasaki-shi (JP); TOSHIBA ELECTRONIC DEVICES & STORAGE CORPORATION, Kawasaki-shi (JP)

(72) Inventor: Kyo Tanabiki, Himeji Hyogo (JP)

(21) Appl. No.: 19/354,531

(22) Filed: Oct. 9, 2025

(30) Foreign Application Priority Data
Mar. 18, 2025 (JP) 2025-043786

(51) Int. Cl. H10W 70/40; H10W 74/10

(52) U.S. Cl. CPC H10W 70/461; H10W 70/415; H10W 70/481; H10W 74/129

(57) ABSTRACT

According to one embodiment, a semiconductor device includes: a semiconductor chip; a first frame electrically connected to a first electrode arranged in a top surface of the semiconductor chip; a second frame electrically connected to a second electrode arranged in a bottom surface of the semiconductor chip; and a sealing material configured to seal the semiconductor chip. The first frame includes a first electrode portion formed in a planar shape and electrically connected to the first electrode, and a first lead extending from the first electrode portion. The first electrode portion is exposed from the sealing material. The second frame includes a second electrode portion formed in a planar shape and electrically connected to the second electrode, a convex portion extending from the second electrode portion and curving so as to protrude downward, and a second lead extending from the convex portion.

### CROSS-REFERENCE TO RELATED APPLICATIONS

This application is based upon and claims the benefit of priority from prior Japanese Patent Application No. 2025-043786, filed March 18, 2025, the entire contents of which are incorporated herein by reference.

### FIELD

Embodiments described herein relate generally to a semiconductor device.

### BACKGROUND

Semiconductor packages having top side cooling structures have recently started to appear on the market due to their excellent heat dissipation properties. However, since such semiconductor packages adopt a connector connection method, they have problems such as (1) the semiconductor chip that can be mounted is small, (2) the heat dissipation area is small, and (3) the on-resistance (Ron) is deteriorated.

Generally, a lead frame used in a semiconductor package includes a bed portion on which a semiconductor chip is placed, and a post portion serving as a lead terminal. The bed portion and the post portion are formed from the same member. For example, if an attempt is made to increase the area of the bed portion having a heat dissipation function, there is a limit due to the constraint of press processing.

### BRIEF DESCRIPTION OF THE DRAWINGS

FIG. 1 is a plan view of a semiconductor device according to the embodiment.

FIG. 2 is a plan view showing the interior of the semiconductor device.

FIG. 3 is a sectional view of the semiconductor device taken along a line A - A' shown in FIG. 1.

FIG. 4 is a sectional view of the semiconductor device taken along a line B - B' shown in FIG. 1.

FIG. 5 is an enlarged partial sectional view of a region C shown in FIG. 3.

FIG. 6 is a sectional view of a semiconductor integrated circuit.

### DETAILED DESCRIPTION

In general, according to one embodiment, there is provided a semiconductor device comprising:

a semiconductor chip;

a first frame electrically connected to a first electrode arranged in a top surface of the semiconductor chip;

a second frame electrically connected to a second electrode arranged in a bottom surface of the semiconductor chip; and

a sealing material configured to seal the semiconductor chip,

wherein

the first frame includes a first electrode portion formed in a planar shape and electrically connected to the first electrode, and a first lead extending from the first electrode portion,

the first electrode portion is exposed from the sealing material, and

the second frame includes a second electrode portion formed in a planar shape and electrically connected to the second electrode, a convex portion extending from the second electrode portion and curving so as to protrude downward, and a second lead extending from the convex portion.

Embodiments will be described below with reference to the accompanying drawings. Several embodiments to be described below will exemplify apparatuses and methods which embody the technical idea of the present invention. The technical idea of the present invention is not specified by the shapes, structures, placements, and the like of components. In the following description, the same reference numerals denote elements having the same functions and configurations, and a repetitive description will be omitted.

### 1 Arrangement of Semiconductor Device 1

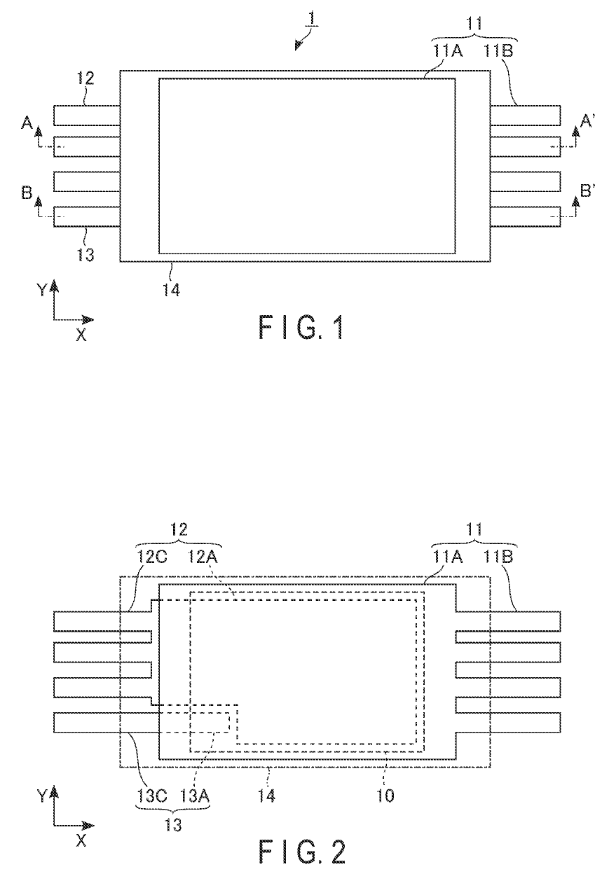

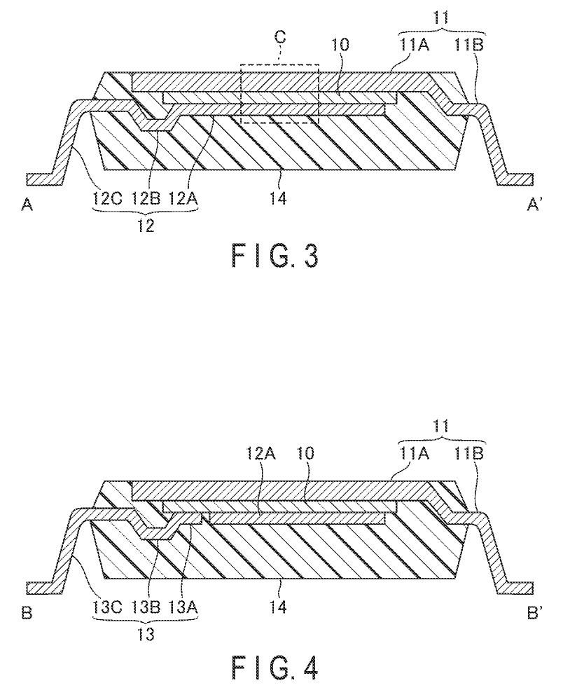

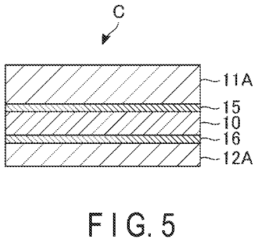

FIG. 1 is a plan view of a semiconductor device 1 according to the embodiment. In FIG. 1, the X direction is a direction along a given side of the semiconductor device 1, and the Y direction is a direction orthogonal to the X direction. FIG. 2 is a plan view showing the interior of the semiconductor device 1. FIG. 2 shows the arrangement of the semiconductor device 1 with a sealing material omitted. FIG. 3 is a sectional view of the semiconductor device 1 taken along a line A - A' shown in FIG. 1. FIG. 4 is a sectional view of the semiconductor device 1 taken along a line B - B' shown in FIG. 1. FIG. 5 is an enlarged partial sectional view of a region C shown in FIG. 3.

The semiconductor device 1 includes a semiconductor chip and a semiconductor package that seals the semiconductor chip. The semiconductor device 1 is formed from, for example, a metal oxide semiconductor field effect transistor (MOSFET) or an insulated gate bipolar transistor (IGBT). In this embodiment, an example will be described in which the semiconductor device 1 is a MOSFET.

The semiconductor device 1 is an element that generates heat when it operates. The semiconductor device 1 can handle a large current, so that it is required to have a high heat dissipation measure. The semiconductor device 1 includes, for example, an element mainly made of Si, an element mainly made of SiC, or the like.

The semiconductor device 1 includes a semiconductor chip 10, a lead frame 11, a clip frame 12, a clip frame 13, and a sealing material 14. The lead frame 11 is also referred to as the first frame. The clip frame 12 is also referred to as the second frame.

The semiconductor chip 10 has, for example, a quadrilateral shape. The semiconductor chip 10 includes a MOSFET or an IGBT. The semiconductor chip 10 includes, for example, a source electrode and a gate electrode in the bottom surface, and a drain electrode in the top surface.

The lead frame 11 includes an electrode portion 11A and a plurality of leads 11B. The lead frame 11 is formed of, for example, copper (Cu). The electrode portion 11A and the plurality of leads 11B are integrally formed using the same material.

The electrode portion 11A is provided on the semiconductor chip 10 via a solder 15. The electrode portion 11A is formed in a planar shape. The electrode portion 11A is electrically connected to the drain electrode of the semiconductor chip 10. The area of the electrode portion 11A is larger than the area of the semiconductor chip 10. In the inverted state of the state shown in FIG. 3, the semiconductor chip 10 is mounted on the electrode portion 11A. The electrode portion 11A is also referred to as a so-called bed portion. The area of the semiconductor chip 10 is limited by the area of the electrode portion 11A. That is, if the area of the electrode portion 11A can be increased, the area of the semiconductor chip 10 can also be increased accordingly. The electrode portion 11A is exposed from the upper portion of the sealing material 14. The electrode portion 11A has a function of dissipating heat generated in the semiconductor chip 10.

The plurality of leads 11B extend from the electrode portion 11A in the Y direction. In this embodiment, a case where four leads 11B are provided is shown as an example. The lead 11B has an L shape (also called a gullwing shape) when viewed from the side.

The clip frame 12 includes an electrode portion 12A, a convex portion 12B, and leads 12C. The clip frame 12 is formed of, for example, copper (Cu). The electrode portion 12A, the convex portion 12B, and the leads 12C are integrally formed using the same material.

The electrode portion 12A is provided under the semiconductor chip 10 via a solder 16. The electrode portion 12A is formed in a planar shape. The electrode portion 12A is electrically connected to the source electrode of the semiconductor chip 10. The area of the electrode portion 12A is appropriately set in accordance with the area of the source electrode. The area of the electrode portion 12A is smaller than the area of the semiconductor chip 10. The area of the electrode portion 12A is also smaller than the area of the electrode portion 11A.

The convex portion 12B is formed to be curved so as to protrude downward. The convex portion 12B is formed to be spaced apart downward from the end portion and side surface of the semiconductor chip 10. The convex portion 12B has a function of preventing the clip frame 12 from touching the side surface of the semiconductor chip 10, thereby preventing short circuit of the electrode or wiring in the semiconductor chip 10.

A plurality of leads 12C extend from the convex portion 12B in a direction opposite to the Y direction. In this embodiment, a case where three leads 12C are provided is shown as an example. The lead 12C has an L shape when viewed from the side.

The clip frame 13 includes an electrode portion 13A, a convex portion 13B, and a lead 13C. The clip frame 13 is formed of, for example, copper (Cu). The electrode portion 13A, the convex portion 13B, and the lead 13C are integrally formed using the same material.

The electrode portion 13A is provided under the semiconductor chip 10 via a solder (not shown). The electrode portion 13A is electrically connected to the gate electrode of the semiconductor chip 10. The area of the electrode portion 13A is appropriately set in accordance with the area of the gate electrode.

The convex portion 13B is formed to be curved so as to protrude downward. The convex portion 13B is formed to be spaced apart downward from the end portion and side surface of the semiconductor chip 10. The convex portion 13B has a function of preventing the clip frame 13 from touching the side surface of the semiconductor chip 10, thereby preventing short circuit of the electrode or wiring in the semiconductor chip 10.

The lead 13C extends from the convex portion 13B in a direction opposite to the Y direction. The lead 13C has an L shape when viewed from the side.

The sealing material 14 seals the semiconductor chip 10, a part of the lead frame 11, a part of the clip frame 12, and a part of the clip frame 13. The sealing material 14 is formed of a resin. The plurality of leads protrude from the sealing material 14. The top surface of the electrode portion 11A of the lead frame 11 is exposed from the sealing material 14.

### 2 Operation

In this embodiment, the clip frame 12 is formed integrally from the electrode portion 12A, the convex portion 12B, and the leads 12C using the same material. The lead frame 11 and the clip frame 12 are formed from individual parts. Accordingly, the X-direction length of the electrode portion 11A of the lead frame 11 is not limited. Therefore, it is possible to set the X-direction length of the electrode portion 11A of the lead frame 11 to be long.

For example, the lead frame 11 (more specifically, the electrode portion 11A) can be extended up to the position where it partially overlaps the lead 12C (a part beyond the convex portion 12B) of the clip frame 12. Hence, the length of the electrode portion 11A having the heat dissipation function can be increased, and the area thereof can also be increased. With this, the heat dissipation property can be improved.

Depending on the specifications of the semiconductor device 1, the lead 12C of the clip frame 12 and the electrode portion 11A of the lead frame 11 may not overlap each other.

The thickness of the electrode portion 11A of the lead frame 11 is set larger than the thickness of the electrode portion 12A of the clip frame 12. With this, the heat dissipation by the lead frame 11 can be improved.

The material of the clip frame 12 may be different from the material of the lead frame 11. The lead frame 11 is electrically connected to the drain electrode of the semiconductor chip 10, and the clip frame 12 is electrically connected to the source electrode of the semiconductor chip 10. In this arrangement example, for example, the electrical conductivity of the clip frame 12 may be set higher than the electrical conductivity of the lead frame 11.

The characteristics of the clip frame 13 are similar to the characteristics of the clip frame 12. The effect of the clip frame 13 is similar to the effect of the clip frame 12.

### 3 Arrangement Example of Semiconductor Integrated Circuit 20

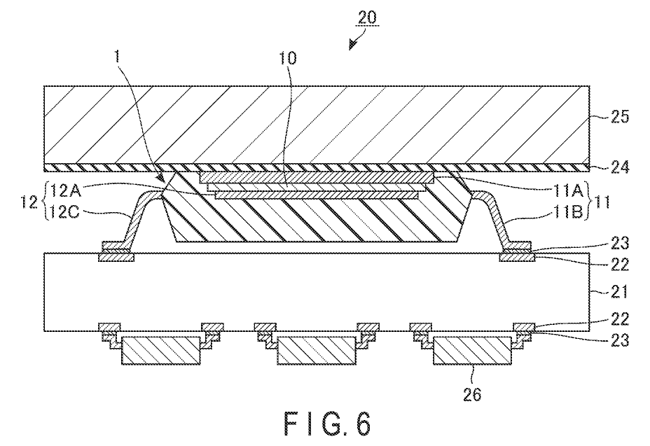

Next, an arrangement example of a semiconductor integrated circuit 20 mounted with the semiconductor device 1 will be described. FIG. 6 is a sectional view of the semiconductor integrated circuit 20.

The semiconductor integrated circuit 20 includes the semiconductor device 1, a printed board 21, a heat sink 25, and a plurality of semiconductor chips 26. The arrangement of the semiconductor device 1 is as described above.

The printed board 21 is formed by providing wirings in a substrate of an insulator. The printed board 21 includes a printed wiring board (PWB) and a printed circuit board (PCB). The printed board 21 includes a plurality of electrodes 22 in its top and bottom surfaces. The plurality of electrodes 22 are exposed in the top or bottom surface of the printed board 21. The electrodes 22 include lands and pads.

The semiconductor device 1 is mounted on, for example, the top surface of the printed board 21. The leads of the semiconductor device 1 are electrically connected to the electrodes 22 of the printed board 21 via solders 23.

The heat sink 25 is provided on the top surface of the semiconductor device 1 via an insulating material 24. The insulating material 24 is formed of an insulating material having a heat dissipation property. The heat sink 25 has a heat dissipation property, and formed of a metal having a high conductivity (that is, a low heat resistance).

The electrode portion 11A of the lead frame 11 is in direct contact with the insulating material 24. Note that in FIG. 6, the lead frame 11 and the clip frame 12 are shown in a simplified form.

Each of the plurality of semiconductor chips 26 is mounted on, for example, the bottom surface of the printed board 21. The plurality of semiconductor chips 26 include passive elements and active elements. The leads of the semiconductor chips 26 are electrically connected to the electrodes 22 of the printed board 21 via the solders 23.

In the semiconductor integrated circuit 20 formed as described above, the heat generated by the semiconductor device 1 is transmitted to the heat sink 25 and dissipated by the heat sink 25. In this embodiment, the area of the electrode portion 11A of the lead frame 11 can be increased. With this, in a case where the semiconductor device 1 is mounted on the printed board 21 or the like, the heat dissipation property of the semiconductor device 1 can be improved.

According to this embodiment, the lead frame 11 and the clip frame 12 are formed by different parts. Accordingly, it is possible to increase the area of the electrode portion 11A of the lead frame 11 without being restricted by the clip frame 12. The electrode portion 11A is exposed from the sealing material 14, thereby having a heat dissipation function. With this, the heat dissipation property of the semiconductor device 1 can be improved.

Since the area of the electrode portion 11A of the lead frame 11 can be increased, the area of the semiconductor chip 10 mounted on the electrode portion 11A can also be increased.

For example, in a case where the electrode portion electrically connected to the source electrode of the semiconductor chip 10 and the lead are formed by different parts, a step of electrically connecting the electrode portion and the lead by a solder or the like is necessary. On the other hand, in this embodiment, the electrode portion 12A, the convex portion 12B, and the lead 12C are formed integrally as the clip frame 12. This can suppress the cost of the semiconductor device 1. This can also suppress deterioration of the on-resistance (Ron).

In addition, the clip frame 12 and the frame 11 can overlap each other. Accordingly, it is possible to manufacture a semiconductor package with a small size without partially decreasing the thickness of the clip frame 12 due to a sharp bend.

In addition, the clip frame 12 can be formed integrally using press processing or the like. Accordingly, it is possible to prevent a partial decrease in the thickness of the clip frame 12. This can suppress deterioration of the on-resistance (Ron) due to the shape of the clip frame 12.

Since each of the lead frame 11 and the clip frame 12 is formed by one part, the number of parts forming the semiconductor device 1 can be reduced.

While certain embodiments have been described, these embodiments have been presented by way of example only, and are not intended to limit the scope of the inventions. Indeed, the novel embodiments described herein may be embodied in a variety of other forms; furthermore, various omissions, substitutions, and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor chip;
a first frame electrically connected to a first electrode arranged in a top surface of the semiconductor chip;
a second frame electrically connected to a second electrode arranged in a bottom surface of the semiconductor chip; and
a sealing material configured to seal the semiconductor chip,
wherein
the first frame includes a first electrode portion formed in a planar shape and electrically connected to the first electrode, and a first lead extending from the first electrode portion,
the first electrode portion is exposed from the sealing material, and
the second frame includes a second electrode portion formed in a planar shape and electrically connected to the second electrode, a convex portion extending from the second electrode portion and curving so as to protrude downward, and a second lead extending from the convex portion.

2. The device according to claim 1, wherein
the second electrode portion, the convex portion, and the second lead, which form the second frame, are integrally formed of the same material.

3. The device according to claim 1, wherein
the first electrode portion is formed to partially overlap the second lead.

4. The device according to claim 1, wherein
an area of the first electrode portion is larger than an area of the second electrode portion.

5. The device according to claim 1, wherein
an area of the first electrode portion is larger than an area of the semiconductor chip.

6. The device according to claim 1, wherein
a thickness of the first electrode portion is larger than a thickness of the second electrode portion.

7. The device according to claim 1, further comprising:
a first solder provided between the semiconductor chip and the first electrode portion; and
a second solder provided between the semiconductor chip and the second electrode portion.

8. The device according to claim 1, wherein
a material of the second frame is the same as a material of the first frame.

9. The device according to claim 1, wherein
a material of the second frame is different from a material of the first frame.

10. The device according to claim 9, wherein
an electrical conductivity of the second frame is higher than an electrical conductivity of the first frame.

11. The device according to claim 1, wherein
each of the first lead and the second lead includes an L-shaped electrode portion.

12. The device according to claim 1, wherein
the semiconductor chip includes a transistor.

13. The device according to claim 12, wherein
the first frame is electrically connected to a drain electrode of the transistor, and
the second frame is electrically connected to a source electrode of the transistor.

14. The device according to claim 1, further comprising:
an insulating material provided on the first electrode portion of the first frame; and
a heat sink provided on the insulating material.

15. The device according to claim 1, wherein
the first frame includes a plurality of first leads, and
the second frame includes a plurality of second leads.
